(19) United States
(12) Patent Application Publication
(10) Pub. No.: US 2025/0157527 A1
(43) Pub. Date: May 15, 2025

(54) APPARATUS WITH MULTI-MODE-REGISTER READ AND WRITE COMMANDS

(71) Applicant: Micron Technology, Inc., Boise, ID (US)

(72) Inventors: Keun-Soo Song, Yokohama (JP); Mark K. Hadrick, Boise, ID (US)

(21) Appl. No.: 18/923,597

(22) Filed: Oct. 22, 2024

Related U.S. Application Data
(60) Provisional application No. 63/598,882, filed on Nov. 14, 2023.

(51) Int. Cl. G11C 11/4096; G11C 11/4093

(52) U.S. Cl. CPC G11C 11/4096; G11C 11/4093

(57) ABSTRACT

Methods, apparatuses, and systems related to operations for executing mode register read and mode register write all commands. A memory device can execute a register read or a mode register write all command using a unit interval of one or more DQs. One or more command address pins can be designated to store groups of mode registers. The memory device can read or write mode register information associated with the group of mode registers through a pre-defined number of DQs, burst length, and die configuration.

### CROSS-REFERENCE TO RELATED APPLICATION(S)

The present application claims priority to U.S. Provisional Patent Application No. 63/598,882, filed Nov. 14, 2023, the disclosure of which is incorporated herein by reference in its entirety.

### TECHNICAL FIELD

The disclosed embodiments relate to devices, and, in particular, to semiconductor memory devices with mode register read and write commands.

### BACKGROUND

An apparatus (e.g., a data processing device, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as Flash memory and dynamic random-access memory (DRAM), can utilize electrical energy to store and access data.

With technological advancements in various areas and increasing applications, the market is continuously looking for faster, more efficient, and smaller devices. To meet the market demand, the semiconductor devices are being pushed to the limit. However, attempts to increase the operating speed and/or to decrease the circuit size often create other issues, such as degraded signal qualities, increased noise, and increased processing errors. In view of the ever-increasing commercial competitive pressures, along with growing consumer expectations and the desire to differentiate products in the marketplace, it is increasingly desirable that answers be found to these problems. Additionally, the semiconductor devices must perform read and write operations at high speeds which can create errors. Moreover, the need to reduce costs, improve efficiencies and performance, and meet competitive pressures adds an even greater pressure to find answers to these problems.

### BRIEF DESCRIPTION OF THE DRAWINGS

FIG. 1A is a block diagram of an example environment in which an apparatus may operate in accordance with an embodiment of the present technology.

FIG. 1B is a block diagram of an apparatus in accordance with an embodiment of the present technology.

FIGS. 2A-2E are diagrams illustrating assignments of mode registers to data input/output (DQ) pins of memory devices, at different die configurations and configured for different burst lengths, used for mode register read all and/or more register write all commands, in accordance with an embodiment of the present technology.

FIG. 3A is a flow diagram illustrating an example method of operating devices for a mode register read all command in accordance with an embodiment of the present technology.

FIG. 3B is a diagram illustrating a command truth table for a mode register read all command in accordance with an embodiment of the present technology.

FIG. 4A is a flow diagram illustrating an example method of operating devices for a mode register write all command, in accordance with an embodiment of the present technology.

FIG. 4B is a diagram illustrating a command truth table for a mode register write all command in accordance with an embodiment of the present technology.

FIG. 4C is a timing diagram illustrating mode register write all command timing in accordance with an embodiment of the present technology.

FIG. 4D is a timing diagram illustrating back-to-back mode register write all commands in accordance with an embodiment of the present technology.

FIG. 5 is a schematic view of a system that includes an apparatus in accordance with an embodiment of the present technology.

### DETAILED DESCRIPTION

As described in greater detail below, the technology disclosed herein relates to an apparatus, such as a memory system, a system with one or more memory devices, a related method, etc., for managing memory-internal operations. In particular, the disclosed technology relates to the improved transfer of data to and from the mode registers of the one or more memory devices.

Currently, due to high operating speeds, memory systems require various training procedures before starting normal data transfer operations. The training procedures may require that a component of the memory system (e.g., a memory controller and/or host) write data to and/or read data from one or more mode registers of the memory devices of the memory system. Additionally, after training, the system may need to continue to read and/or write mode register information regularly or irregularly. Memory systems may support a mode register read (MRR) command, through which a host may read data from a mode register of a memory device, and a mode register write (MRW) command, through which a host may write data to a mode register of a memory device. In some memory systems (e.g., memory systems that comply with certain versions of the Double Data Rate (DDR) synchronous DRAM (SDRAM) standard, such as DDR5), each MRR and/or MRW command addresses a single mode register. For example, a MRR command issued by a host may specify a single mode register (e.g., as part of the command), and the memory device may send the data from that mode register on all data pins (DQs) of the memory device over multiple UIs of a burst. As a further example, a MRW command issued by a host may specify a single mode register (e.g., as part of the command) as well as the data to be written to that mode register (e.g., as another part of the command). For example, the host may indicate the mode register to be read from or written to using one or more command address (CA) signals received by the memory device. In said memory systems, in which each MRR and/or MRW command issued by a host provides access to a single mode register, the host must issue multiple MRR and/or MRW commands to access multiple mode registers. Because in such memory systems accessing various mode registers requires multiple commands (e.g., a host that needs to write to 15 different mode registers would need to issue 15 corresponding MRW commands), writing or reading mode register bits from various mode registers can cause latency in the system which reduces performance. Thus, there is a need for a memory system with commands to read and write multiple mode registers at a time (a “memory system with multi-mode-register read and write commands”), to support efficiently transferring mode register related data between a memory device and a host.

Accordingly, embodiments of a memory system with multi-mode-register read and write commands provide a command to read data from multiple mode registers (a MRR-ALL command) and/or a command to write data to multiple mode registers (a MRW-ALL command). As described herein, the MRR-ALL and/or MRW-ALL commands can be configured to transmit data for different mode registers using one or more DQs of a memory device, over multiple UIs of a burst. Although referred to herein as MRR-ALL and MRW-ALL commands, in some embodiments each issued command is capable of accessing multiple mode registers of a memory device, but not all mode registers of the memory device. As described herein, in embodiments of the memory system with multi-mode-register read and write commands, the mode registers of a memory device (or a subset of the mode registers) are divided into one or more groups of mode registers, and each issued MRR-ALL and/or MRW-ALL command may access all of the mode registers belonging to the group identified by the issued command. The MRR-ALL and/or MRW-ALL command can be used in a low frequency operation before an apparatus completes training and/or in a high frequency operation after the apparatus completes trainings (e.g., write/read trainings).

In some embodiments of a MRR-ALL command, one or more CA signals between the host and memory device are used to indicate a group. Each group may be associated with one or more mode registers (e.g., a group A may be associated with mode registers 0-3, a group B may be associated with mode registers 4-7, etc.), and the contents of the different mode registers associated with the indicated group may be read in response to the MRR-ALL command. As described herein, the contents of each mode register belonging to the indicated group (e.g., OP0-OP7 of each mode register) may be transmitted over the DQs between the memory device and host during the UIs that make up a burst. The DQ used to transmit the contents of a particular mode register in the group, and the UIs during which that mode registers contents will be transmitted, may be pre-defined. In some embodiments, the number of groups and the CA pins can be pre-defined. When a host sends an MRR-ALL command to the memory device, the memory device retrieves the mode register information for the mode registers belonging to the group designated by the MRR-ALL command. Since the information from different mode registers is sent over several DQs, the host can receive mode register information of multiple mode registers in response to a single command (e.g., MRR-ALL). To receive the mode register information from a designated group, the host can flag the associated CA pins as “high” when issuing the MRR-ALL command. Upon receiving the MRR-ALL command, the memory device will respond with the mode register information from the designated group of mode registers.

In some embodiments of a MRW-ALL command, one or more CA signals between the host and memory device are used to indicate a group. As described above, each group may be associated with one or more mode registers, and the different mode registers associated with the indicated group may be written-to based on the MRW-ALL command. As described herein, the contents to be written to each mode register belonging to the indicated group (e.g., OP0-OP7 of each mode register) may be transmitted over the DQs between the host and the memory device during the UIs that make up a burst. The DQ used to transmit the contents to be written to a particular mode register in the group, and the UIs during which that mode registers contents will be transmitted, may be pre-defined. In some embodiments, the number of groups and the CA pins can be pre-defined. When a host sends an MRW-ALL command to the memory device, the memory device stores the mode register information into the mode registers belonging to the group designated by the MRW-ALL command. Since the information to be written to the different mode registers is transmitted over several DQs, the host can send mode register information of multiple mode registers as part of a single command (e.g., MRW-ALL). To store the mode register information to a specific group, the host can flag the associated CAs pin as “high” when issuing the MRW-ALL command. Upon receiving the MRW-ALL command, the memory device stores the mode register information to the mode registers belonging to the specific group.

As described in greater detail below, the grouping of a memory device's mode registers into groups may depend on the configuration of the memory device. For example, memory devices may have different die configurations associated with the number of DQ pins of the memory device. That is, some memory devices may have 4 DQ pins (referred to as a x4 device, having DQ0-DQ3), some memory devices may have 8 DQ pins (referred to as a x8 device, having DQ0-DQ7), some memory devices may have 16 DQ pins (referred to as a x16 device, having DQ0-DQ15), etc. As a further example, memory devices may be configured with different burst lengths (e.g., the amount of data transmitted over a DQ pin following a command). That is, some memory devices may have a burst length of 16 (referred to as BL16, in which data is transmitted over a DQ over 16 UIs), some memory devices may have a burst length of 32 (referred to as BL32, in which data is transmitted over a DQ over 32 UIs, etc.). Based on the die configuration of the memory device (e.g., how many DQ pins the memory device has) and/or the burst length configuration of the memory device (e.g., over how many UIs data can be transmitted over each DQ), the total amount of data that can be transmitted over the memory devices DQ pins in association with a MRR-ALL or MRW-ALL command changes, and the number of mode registers that may be assigned to a group (and the group composition) changes accordingly. For example, a x16 memory device configured to BL16 can transmit 256 bits of data over the DQ pins as part of a MRR-ALL or MRW- ALL command (e.g., 16 DQ pins, multiplied by 16 UIs per DQ). In an embodiment in which each mode register has 8 bits of information (e.g., OP0-OP7), the x16/BL16 memory device could therefore transmit the contents corresponding to 32 mode registers over the DQs in response to a MRR-ALL or MRW-ALL command (e.g., 256 bits of data over the DQs, divided by 8 bits of data per mode register). As a further example, a x4 memory device configured to BL16 could transmit the contents of 8 mode registers per MRR-ALL or MRW-ALL command, assuming 8 bits of information per mode registers. Accordingly, the size of a group (e.g., the number of mode registers assigned to a group) may change depending on the memory device configuration, such that the data associated with all mode registers in a group can be transmitted as part of a MRR-ALL or MRW-ALL command issued to that memory device. For example, a x16/BL16 memory device may have a group size of 32, whereas a x4/BL16 memory device may have a group size of 8. Similarly, the mode registers within a group may be assigned to the DQs of the memory device depending on the memory device configuration. Accordingly, and as described in greater detail herein, components of a memory system with multi-mode-register read and write commands (e.g., hosts, memory controllers, and/or memory devices) may associate different mode registers with groups, corresponding to different group sizes, transmitted over different DQs at different UIs, depending on the configuration of memory devices within the memory system.

As described in detail below, embodiments of the present technology can provide technical advantages over conventional technology. For example, by grouping multiple mode registers into groups, where each group is sized such that information corresponding to all of the mode registers within the group can be transmitted during a burst, the memory system with multi-mode-register read and write commands can provide information associated with additional (e.g., 8*X the number of mode registers) mode registers in the same amount of time that conventional techniques provide the information associated with a single mode register. The mode registers that form a group for the MRW-ALL command can be different or the same as the mode registers that form a group for the MRR-ALL command.

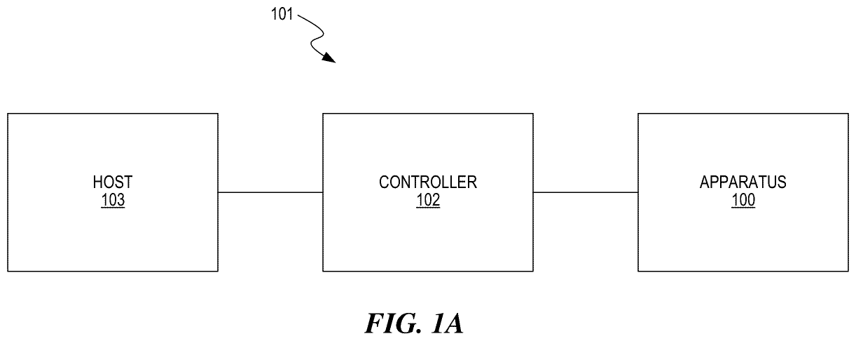

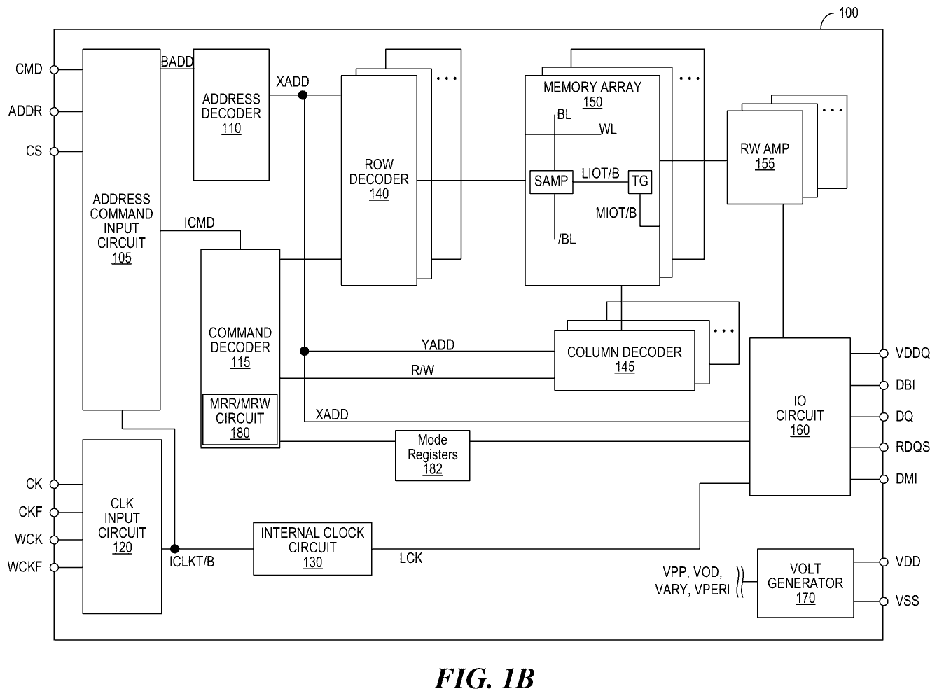

FIG. 1A is a block diagram of an example environment 101 in which an apparatus 100 may operate in accordance with an embodiment of the present technology. The example environment 101 can correspond to a computing device or system. As described in detail below, the apparatus 100 can include a memory device or system, such as a volatile memory, a non-volatile memory, or a combination device/system. For example, the apparatus 100 can include a DRAM.

The apparatus 100 can be electrically coupled to an apparatus controller 102 (e.g., a memory controller, a buffer, a repeater device, such as an RCD, etc.) and a host 103 (e.g., one or more processors). Some example operating environments can include a computing system having a central processing unit (CPU) as the host 103 interacting with an apparatus controller 102 to write data to and read data from a DRAM (the apparatus 100). The host 103 can function according to an operating system and send operational communications (e.g., read/write commands, MRR-ALL commands, MRW- ALL commands, write data, addresses, etc.) to the apparatus controller 102. The apparatus 100 can also send read data back to the apparatus controller 102 as the operational communications. The apparatus controller 102 can manage the flow of the data to or from the apparatus 100 according to the address and/or the operation.

FIG. 1B is a block diagram of the apparatus 100 (e.g., a semiconductor die assembly, including a 3DI device or a die-stacked package) in accordance with an embodiment of the present technology. For example, the apparatus 100 can include a DRAM (e.g., DDR DRAM, such as DDR4 or DDR5 DRAM, LP DRAM, HBM DRAM, etc.), or a portion thereof.

The apparatus 100 may include an array of memory cells, such as memory array 150. The memory array 150 may include a plurality of banks (e.g., banks 0-15), and each bank may include a plurality of word lines WL, a plurality of bit lines BL, and a plurality of memory cells arranged at intersections of the word lines and the bit lines. Memory cells can include any one of a number of different memory media types, including capacitive, magnetoresistive, ferroelectric, phase change, or the like. The selection of a word line (WL) may be performed by a row decoder 140, and the selection of a bit line BL may be performed by a column decoder 145. Sense amplifiers (SAMP) may be provided for corresponding bit lines BL and connected to at least one respective local I/O line pair (LIOT/B), which may in turn be coupled to at least respective one main I/O line pair (MIOT/B), via transfer gates (TG), which can function as switches. The memory array 150 may also include plate lines and corresponding circuitry for managing their operation.

The apparatus 100 may employ a plurality of external terminals that include command and address terminals coupled to a command bus and an address bus to receive command signals (CMD) and address signals (ADDR), respectively. The apparatus 100 may further include a chip select terminal to receive a chip select signal (CS), clock terminals to receive clock signals CK and CKF, data clock terminals to receive data clock signals WCK and WCKF, data terminals DQ, RDQS, DBI, and DMI, power supply terminals VDD, VSS, and VDDQ.

The command terminals and address terminals may be supplied with an address signal and a bank address signal (not shown in FIG. 1B) from outside. The address signal and the bank address signal supplied to the address terminals can be transferred, via a command/address input circuit 105, to an address decoder 110. The address decoder 110 can receive the address signals and supply a decoded row address signal (XADD) to the row decoder 140, and a decoded column address signal (YADD) to the column decoder 145. The address decoder 110 can also receive the bank address signal and supply the bank address signal to both the row decoder 140 and the column decoder 145.

The command and address terminals may be supplied with command signals (CMD), address signals (ADDR), and chip select signals (CS), from a memory controller (e.g., the apparatus controller 102 of FIGS. 1A, 2A, and 3A). The command signals may represent various memory commands from the memory controller (e.g., including access commands, which can include read commands and write commands). The chip select signal may be used to select the apparatus 100 to respond to commands and addresses provided to the command and address terminals. When an active chip select signal is provided to the apparatus 100, the commands and addresses can be decoded and memory operations can be performed. The command signals may be provided as internal command signals ICMD to a command decoder 115 via the command/address input circuit 105. The command decoder 115 may include circuits to decode the internal command signals ICMD to generate various internal signals and commands for performing memory operations, for example, a row command signal to select a word line and a column command signal to select a bit line. The command decoder 115 may further include one or more registers for tracking various counts or values (e.g., counts of refresh commands received by the apparatus 100 or self-refresh operations performed by the apparatus 100).

Read data can be read from memory cells in the memory array 150 designated by row address (e.g., address provided with an active command) and column address (e.g., address provided with the read). The read command may be received by the command decoder 115, which can provide internal commands to input/output circuit 160 so that read data can be output from the data terminals DQ, RDQS, DBI, and DMI via read/write amplifiers 155 and the input/output circuit 160 according to the RDQS clock signals. The read data may be provided at a time defined by read latency information RL that can be programmed in the apparatus 100, for example, in a mode register (not shown in FIG. 1B). The read latency information RL can be defined in terms of clock cycles of the CK clock signal. For example, the read latency information RL can be a number of clock cycles of the CK signal after the read command is received by the apparatus 100 when the associated read data is provided.

Write data can be supplied to the data terminals DQ, DBI, and DMI according to the WCK and WCKF clock signals. The write command may be received by the command decoder 115, which can provide internal commands to the input/output circuit 160 so that the write data can be received by data receivers in the input/output circuit 160, and supplied via the input/output circuit 160 and the read/write amplifiers 155 to the memory array 150. The write data may be written in the memory cell designated by the row address and the column address. The write data may be provided to the data terminals at a time that is defined by write latency WL information. The write latency WL information can be programmed in the apparatus 100, for example, in the mode register (not shown in FIG. 1B). The write latency WL information can be defined in terms of clock cycles of the CK clock signal. For example, the write latency information WL can be a number of clock cycles of the CK signal after the write command is received by the apparatus 100 when the associated write data is received.

The power supply terminals may be supplied with power supply potentials VDD and VSS. These power supply potentials VDD and VSS can be supplied to an internal voltage generator circuit 170. The internal voltage generator circuit 170 can generate various internal potentials VPP, VOD, VARY, VPERI, and the like based on the power supply potentials VDD and VSS. The internal potential VPP can be used in the row decoder 140, the internal potentials VOD and VARY can be used in the sense amplifiers included in the memory array 150, and the internal potential VPERI can be used in many other circuit blocks.

The power supply terminal may also be supplied with power supply potential VDDQ. The power supply potential VDDQ can be supplied to the input/output circuit 160 together with the power supply potential VSS. The power supply potential VDDQ can be the same potential as the power supply potential VDD in an embodiment of the present technology. The power supply potential VDDQ can be a different potential from the power supply potential VDD in another embodiment of the present technology. However, the dedicated power supply potential VDDQ can be used for the input/output circuit 160 so that power supply noise generated by the input/output circuit 160 does not propagate to the other circuit blocks.

The clock terminals and data clock terminals may be supplied with external clock signals and complementary external clock signals. The external clock signals CK, CKF, WCK, WCKF can be supplied to a clock input circuit 120. The CK and CKF signals can be complementary, and the WCK and WCKF signals can also be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 120 can receive the external clock signals. For example, when enabled by a clock/enable signal from the command decoder 115, an input buffer can receive the clock/enable signals. The clock input circuit 120 can receive the external clock signals to generate internal clock signals ICLK. The internal clock signals ICLK can be supplied to an internal clock circuit 130. The internal clock circuit 130 can provide various phase and frequency controlled internal clock signals based on the received internal clock signals ICLK and a clock enable (not shown in FIG. 1B) from the command/address input circuit 105. For example, the internal clock circuit 130 can include a clock path (not shown in FIG. 1B) that receives the internal clock signal ICLK and provides various clock signals to the command decoder 115. The internal clock circuit 130 can further provide input/output (IO) clock signals. The IO clock signals can be supplied to the input/output circuit 160 and can be used as a timing signal for determining an output timing of read data and the input timing of write data. The IO clock signals can be provided at multiple clock frequencies so that data can be output from and input to the apparatus 100 at different data rates. A higher clock frequency may be desirable when high memory speed is desired. A lower clock frequency may be desirable when lower power consumption is desired. The internal clock signals ICLK can also be supplied to a timing generator and thus various internal clock signals can be generated.

The apparatus 100 can be connected to any one of a number of electronic devices capable of utilizing memory for the temporary or persistent storage of information, or a component thereof. For example, the host device and the apparatus 100 may be included in a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.).

The apparatus 100 can include a MRR/MRW circuit 180. The MRR/MRW circuit 180 can be included in or coupled to circuits receiving signals from an external source. For example, the MRR/MRW circuit 180 can be included in or coupled to the command/address input circuit 105, the clock input circuit 120, and/or the IO circuit 160. The MRR/MRW circuit 180 can be configured to receive MRR-ALL commands and/or MRW-ALL commands from an external source, such as the apparatus controller 102 of FIG. 1A. The MRR/MRW circuit 180 can store mode register information to or retrieve mode register information from one or more mode registers 182. Mode registers 182 can be organized into one or more groups. Each group is associated with specific mode registers, from the mode registers 182, to which information is stored during a write operation (e.g., in response to a MRW-ALL command), or from which information is read during a read operation (e.g., in response to a MRR-ALL command). The group to be read from and/or written to may be indicated by one or more of the command and/or address signals. In some embodiments, one or more individual bits of the command and/or address signals may be associated with individual groups, and asserting a bit selects the corresponding group (e.g., one bit may be used to select a group A, another bit may be used to select a group B, and another bit may be used to select a group C). In some embodiments, one or more bits of the command and/or address signals are used to encode a group identifier (e.g., three command/address signals may be used to encode an identifier for one of group A through group H). The MRR/MRW circuit 180 can determine which mode registers from mode registers 182 belong to a selected group based on the configuration of apparatus 100 (e.g., based on the number of DQs, burst length, and/or die configuration). During a burst, the apparatus 100 can send or receive the information of different mode registers (e.g., OP0-OP7), via the DQs at specific UIs, as determined by the MRR/MRW circuit 180 and/or command decoder 115. For example, in response to a MRR-ALL command the apparatus 100 may transmit the contents of a first mode register over DQ0 during UI0-UI7, and transmit the contents of a second mode register over DQ0 during I8-UI15. The contents of other mode registers may be transmitted over other DQs (e.g., DQ1-DQ15) and/or other UIs (e.g., UI16-UI31), where the mode registers from which the information is read is based on the selected group, depending on the configuration of the apparatus 100. Similarly, during a MRW-ALL command the apparatus 100 may receive the information to be written to the different mode registers within the selected group over the DQs at different UIs within the burst. The command decoder 115 (or MRR/MRW circuit 180) can send/receive signals to the one or more mode registers of mode registers 182, to store or retrieve data, based on the group selection indicated by the command and address pins. The signals can include mode register selection (e.g., which mode registers are being read from or written to), operand data from a CA (e.g., data to be written to a mode register provided over a command/address bus, such as for a conventional MRW command), operand data from a DQ (e.g., data to be written to a mode register provided over a data bus, such as for a MRW-ALL command), a MRR command control enable signal (e.g., when the apparatus receives a conventional MRR command), a MRW command control enable signal (e.g., when the apparatus receives a conventional MRW command), a MRR-ALL command control enable signal (e.g., when the apparatus receives a MRR-ALL command), and/or a MRW-ALL command control enable signal (e.g., when the apparatus receives a MRW- ALL command). In an MRW-ALL command, the data (e.g., write leveling data) is received through DQs of IO circuit 160 and sent to the selected mode registers 182.

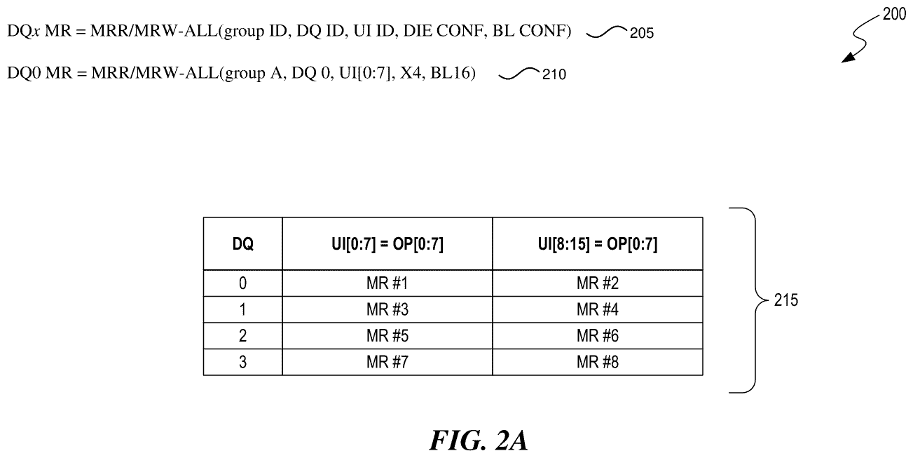

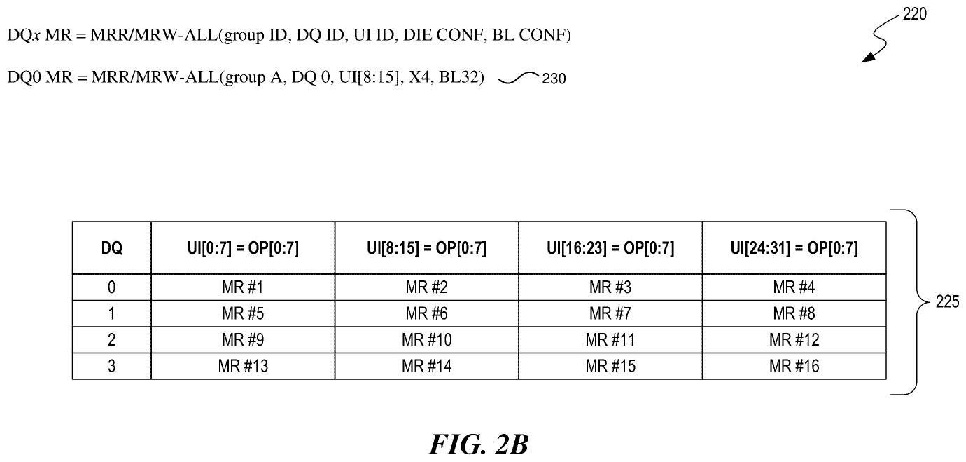

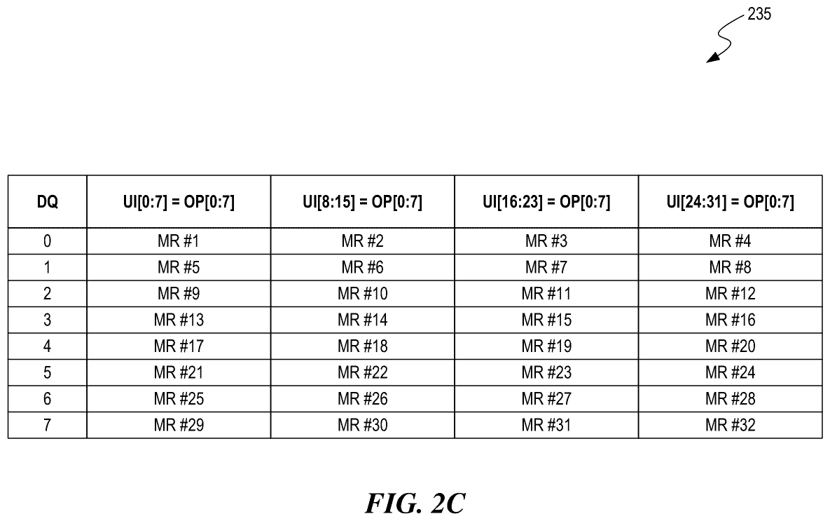

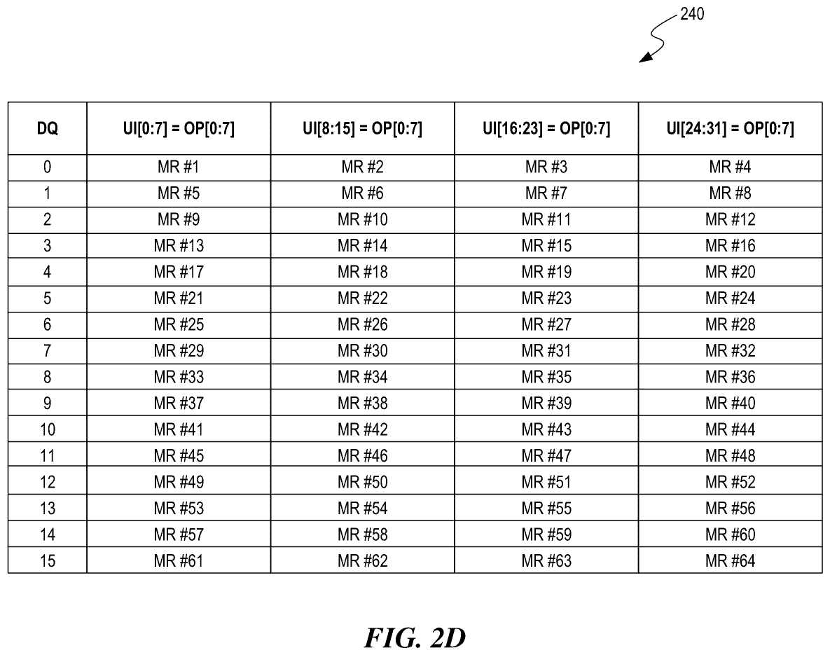

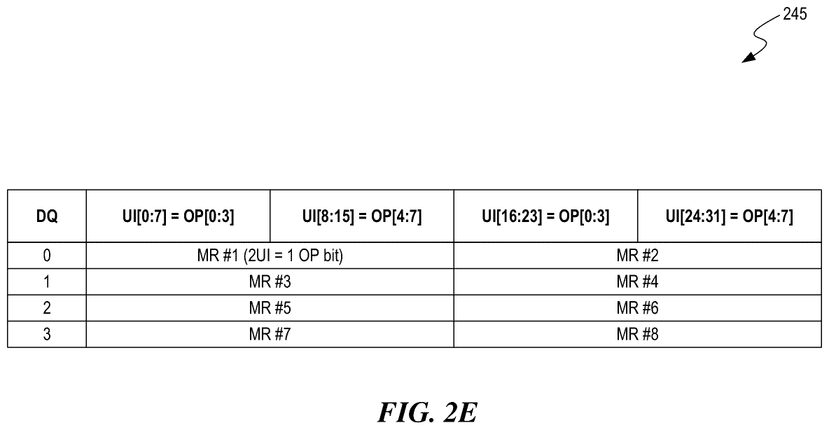

FIG. 2A is a diagram illustrating an assignment 200 of mode registers to DQ pins of a x4 memory device configured to BL16, in accordance with an embodiment of the present technology. As illustrated by MRR/MRW-ALL assignment logic 205, the mode register associated with a given DQ may be based on the mode register group (e.g., as indicated by an MRR-ALL and/or MRW-ALL command), the DQ identifier (e.g., which of DQ0-DQ3), the UI identifier (e.g., the position within a burst), the die configuration of the memory device (e.g., how many DQ pins), and/or the burst length. For example, in an x4 memory device configured to BL16, if a MRR-ALL and/or MRW-ALL command selects mode register group A, then DQ0 will be used for the data of a designated mode register during UI[0:7] of a burst (illustrated by decode 210), and used for a different designated mode register during UI[8:15] of the burst. Table 215 illustrates an example assignment for a single group (e.g., group A) for an x4 memory device configured to BL16. As illustrated in FIG. 2A, in the example assignment 200 the group A consists of mode registers MR #1 through MR #8. As reflected in the table 215, in the example assignment 200 the contents of MR #1, MR #3, MR #5, and MR #7 are transmitted over DQ0-DQ3 during the first half of a burst (e.g., UI0-UI7), and the contents of MR #2, MR #4, MR #6, and MR #8 are transmitted over DQ0-DQ3 during the second half of the burst (e.g., UI8-UI15). That is, as illustrated in FIG. 2A, in an embodiment in which each mode register contains 8 bits of information (e.g., OP0-OP7), then a MRR-ALL and/or MRW-ALL command enables transmitting the contents of 8 total mode registers when used with an x4 memory device configured to BL16. It will be appreciated in that in some embodiments, other mode registers may be associated with a particular mode register group.

FIG. 2B is a diagram illustrating an assignment 220 of mode registers to the DQ pins of a x4 memory device configured to BL32, in accordance with an embodiment of the present technology. Table 225 illustrates an example assignment of a single group (e.g., group A) for an x4 memory device configured to BL32. As illustrated in FIG. 2B, in the example assignment 220 the group A consists of mode registers MR #1 through MR #16. As reflected in the table 225, in the example assignment 220 the contents of a first set of mode registers within the group are transmitted over the first portion of a burst (e.g., UI0-UI7, the contents of a second set of mode registers within the group are transmitted over the second portion of a burst (e.g., UI8-UI15), etc. For example, in an embodiment the contents of MR #2 are transmitted using DQ0 during UI8-UI15 of a burst (illustrated by decode 230).

FIGS. 2C and 2D illustrate mode register assignments for other configurations of memory devices. For example, FIG. 2C illustrates an assignment 235 of mode registers to the DQ pins of a x8 memory device configured to BL32, and FIG. 2D illustrates an assignment 240 of mode registers to the DQ pins of a x16 memory device configured to BL32. As illustrated in FIGS. 2C and 2D, the number of mode registers for which content may be transmitted (e.g., from the memory device during a MRR-ALL or to the memory device during a MRW-ALL) over the DQs during a burst may increase as the number of DQ pins of the memory device increases.

FIG. 2E is a diagram illustrating an assignment 245 for a x4 memory device configured for BL32, in accordance with an embodiment of the present technology. As illustrated in assignment 245, each bit of mode register information is transmitted over two UIs, therefore providing an additional timing margin (e.g., in contrast to the assignment 200 illustrated in FIG. 2A). For example, as illustrated in FIG. 2E, the contents of MR #1 may be transmitted over UI0-UI15, where half of the mode register contents (OP0-OP3) are transmitted over UI0-UI7, and the other half of the most register contents (OP4-OP7) are transmitted over UI8-UI15. That is, in the assignment 245 the contents of fewer mode registers can be transmitted during a burst, but greater timing margins are provided for transmitting each bit of a mode registers. Although FIG. 2E illustrates an assignment 245 for a representative group (e.g., “group A”) on a x4 memory device with a burst length of 32, assignments in which each bit of mode register data is transmitted over two UIs can include assignments for other groups and/or other memory device configurations. Although assignment 245 illustrates one OP-bit spanning two UIs, the present technology can be applied to one OP-bit spanning any number of unit intervals. For example, each OP-bit of a mode register could be transmitted over four UIs for further improved timing margin. In some embodiments, different command and/or configuration settings can be used to indicate over how many UIs each OP-bit of a mode register will be transmitted.

Although FIGS. 2A-2E illustrate assignments for a single group (e.g., group A), it is understood that the techniques described herein can be applied to support other groups (e.g., group B, group C, etc.). Further, the representation of certain mode registers in FIGS. 2A-2E (e.g., MR #1, MR #2, MR #3, etc.) are for illustrative purposes only, and it will be appreciated that the present technology assignment applies to other mode registers and to other mode register groups. Further, the mode registers assigned to a single group need not be consecutively numbered. For example, a group (e.g., group A) consisting of four total mode registers could include MR 190 5, MR #13, MR #16, and MR #28. Each assignment can support a unique assignment of different mode registers to each group. Additionally, the system described herein can use the same assignment table for MRR-ALL commands as well as MRW-ALL commands. In some embodiments, the mode register-to-group assignments can be done differently for MRR-ALL commands and MRW-ALL commands.

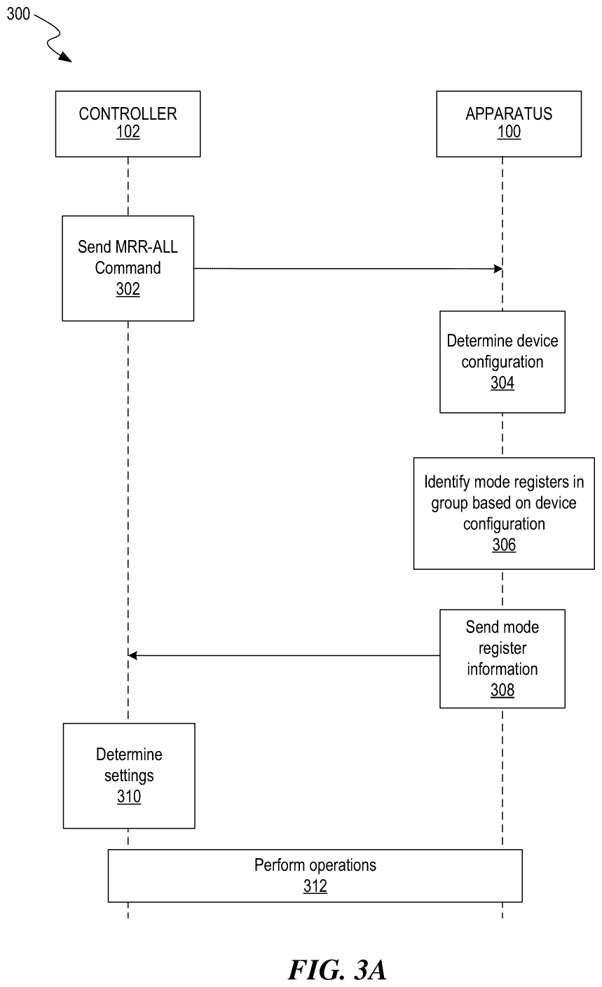

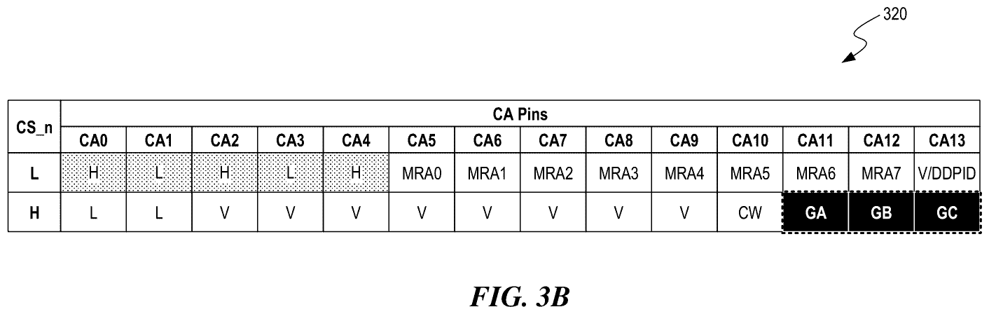

FIG. 3A is a flow diagram illustrating an example method 300 of operating devices (e.g., devices illustrated in FIGS. 1A, and/or 1B) for a MRR-ALL command in accordance with an embodiment of the present technology. The example method 300 can correspond to operations of a computing device or system, such as including the apparatus 100 (e.g., a DRAM) that is electrically coupled to the apparatus controller 102 (e.g., a memory controller). The apparatus controller 102 and the apparatus 100 can interact with each other in real-time, such as during system initialization and/or actual use by an end-user, to perform MRR-ALL operations. The apparatus controller 102 and the apparatus 100 can use the MRR-ALL operations to transmit (e.g., from the apparatus 100 to the apparatus controller 102) the contents of multiple mode registers of the apparatus. As described herein, the mode registers may contain data characterizing the configuration of the apparatus 100, operational parameters of the apparatus, status of the apparatus, etc.

At block 302, the apparatus controller 102 can send an MRR-ALL command to the apparatus 100. The apparatus controller 102 can be configured to send an MRR-ALL command during operation of the corresponding system/environment. For example, the apparatus controller 102 can be configured to read one or more mode registers of the apparatus 100 to train an interface of the apparatus (e.g., CA/CS/CK) upon system power-up or the corresponding system initialization. The MRR-ALL command sent by the apparatus controller 102 may indicate a mode register group, from which to read mode register information. For example, one or more bits used to send the MRR-ALL command (e.g., CA bits) may be used to encode a group identifier and/or individual bits may be used to designate a specific group. In an embodiment in which the apparatus 100 is coupled to a 14-bit CA interface (e.g., CA[13:0]), CA[13:11] may be used to indicate the group.

At block 304, the apparatus 100 can determine the device configuration of the apparatus, in response to receiving the MRR-ALL command from the apparatus controller 102. For example, the apparatus may activate the MRR/MRW circuit 180 of FIG. 1B. The apparatus 100 can determine one or more aspects of the device configuration that are associated with how much data the apparatus can send in response to the MRR-ALL command. For example, the apparatus 100 can determine the die configuration of the apparatus (e.g., how many DQs couple the apparatus to the apparatus controller 102) and the burst length of the apparatus.

At block 306, the apparatus 100 can identify the mode registers belonging to the group indicated by the MRR-ALL command, based on the device configuration of the apparatus. For example, during the sending of the MRR-ALL command one or more CA pins (e.g., CA11, CA12, and CA13 as illustrated in FIG. 3B) can be used to indicate the group of mode registers requested by the apparatus controller 102. Each group defines one or more mode registers that are read in response to the MRR-ALL command. As described herein, the composition of each group (e.g., the number of mode registers associated with a group, and which mode registers are associated with a group) may depend on one or more aspects of the device configuration of the apparatus 100 (e.g., the number of DQs and burst length). Furthermore, how the information from the mode registers associated with the indicated group are transmitted may depend on one or more aspects of the device configuration of the apparatus 100. For example, which DQ is used to transmit a mode register's information, and during which UIs within the burst, may be determined by the apparatus 100. The apparatus 100 may determine which mode registers belong to a given group and how the information of the mode registers is to be transmitted, based on the device configuration, using one or more of dedicated logic, configurable logic, look-up table, etc. For example, the apparatus 100 may include a look-up table configured to receive as inputs a group identifier and device configuration aspects, and provide as outputs the mode registers belonging to that group and how the mode register information will be transmitted (e.g., over which DQ during which UIs). Although described in the context of the apparatus 100, the apparatus controller 102 may include similar functionality (e.g., to determine which group to request to receive information from desired mode registers and/or to determine when to expect the mode register information to be transmitted over a DQ). In embodiments, not all mode registers of the apparatus 100 are associated with a group and/or some mode registers of the apparatus may be associated with more than one group. For example, in an apparatus 100 with 256 mode registers, only 64 mode registers (e.g., the mode registers that store information used during training operations) may be associated with one or more groups that can be selected by a MRR-ALL command. During a training operation, a subset of the mode registers may be read from instead of all of the mode registers.

At block 308, the apparatus 100 can send the mode register contents (e.g., OP0-OP7) for one or more mode registers, in response to the MRR-ALL command, to the apparatus controller 102. As described herein, the apparatus 100 can send the contents of the one or more mode registers, on a DQ, over one or more UIs within a bust. For example, the apparatus 100 may send the contents of a first mode register over DQ0, and the contents of a second more register over DQ1, during first UIs of a burst (e.g., UI0-UI7), followed by sending the contents of a third mode register over DQ0 and the contents of a fourth mode register over DQ1 during second UIs of the burst (e.g., UI8-UI15). The mode registers to be read may be based on the group indication of the MRR-ALL command, based on which the apparatus 100 can determine which mode registers belong to the group and how the mode registers contents should be transmitted (e.g., over which DQ and during which UIs), based e.g., on block 306. Since the mode register contents are sent over several DQs, the apparatus controller 102 can receive mode register information of multiple mode registers at the same time in response to the MRR-ALL command.

At block 310, the apparatus controller 102 can determine a configuration setting and/or status of the apparatus 100 based on the mode register information received in response to the MRR-ALL command. For example, the apparatus controller 102 can determine a status of the apparatus 100 relevant to training.

At block 312, the apparatus controller 102, the apparatus 100, or a combination thereof can perform one or more operations based on the determined configuration settings and/or status. For example, the apparatus controller 102 and/or the apparatus 100 can adjust a setting used during training.

Although FIG. 3A illustrates an embodiment of the method 300 in which the apparatus 100 and/or apparatus controller 102 use mode register information read via an MRR-ALL command to perform training, information read from the mode registers may be used for other purposes of the memory system.

FIG. 3B is a diagram illustrating a command truth table 320 for a MRR-ALL command in accordance with an embodiment of the present technology. The command truth table 320 illustrates that during a first cycle of the MRR-ALL command (e.g., when CS_n is L), CA5-CA12 may be used to encode an address (MRA0-MRA7) of an individual mode register. The individual mode register address may be used to identify an individual mode register to read when, as described below, the MRR-ALL command is decoded as a MRR command. The command truth table 320 further illustrates that during a second cycle of the MRR-ALL command (e.g., when CS_n is H), CA11, CA12, and CA13 are used to indicate a group. In the embodiment illustrated in FIG. 3B, each of CA11, CA12, and CA13 indicate an individual group, e.g., CA11 indicates group A, CA12 indicates group B, and CA13 indicates group C. In embodiments in which each CA pin indicates an individual group, zero or one of the pins may be asserted to be a valid MRR-ALL command (e.g., multiple pins cannot assert to indicate multiple groups). In embodiments (not shown), CA11-CA13 may be used to store an encoded group identifier. Although for illustrative purposes only three CA pins, associated with three groups of mode registers are shown, the current techniques can include any number of mode register groups, and indicated by encoded or decoded (e.g., zero-or one-hot) form. In embodiments, if the MRR-ALL command indicates a valid group identifier during the second cycle (e.g., on CA11-CA13), then the more register address (MRA0-MRA7) of the first cycle is ignored. For example, the MRA0-MRA7 bits become “don't cares” if on the next phase (when CS_n goes H) the rest of the decode indicates the MRR-ALL instruction and not an MRR instruction (e.g., based on the presence of the GA, GB, and GC bits). In embodiments, if the MRR-ALL command does not include a group identifier during the second cycle, then the command causes a read from the mode register associated with the mode register address information of the first cycle (e.g., as a conventional MRR command).

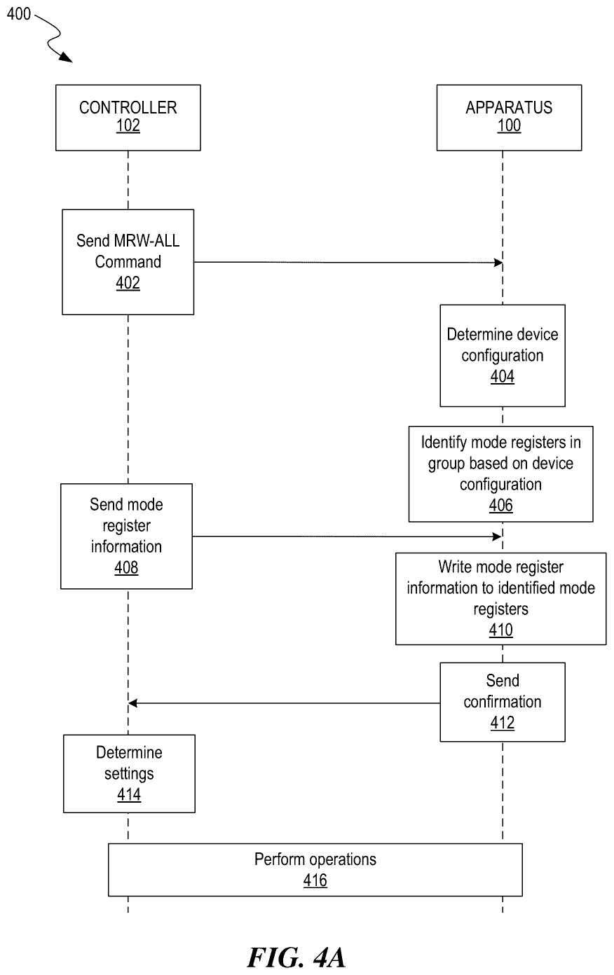

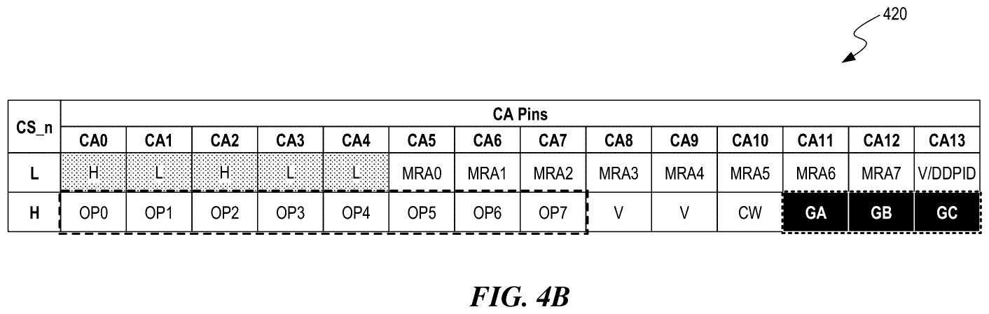

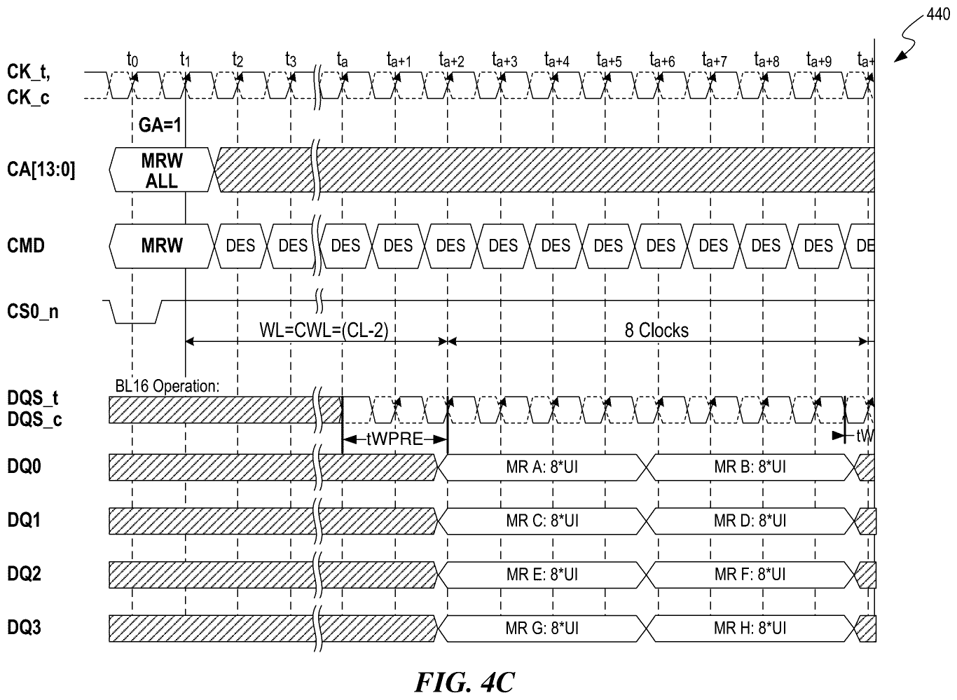

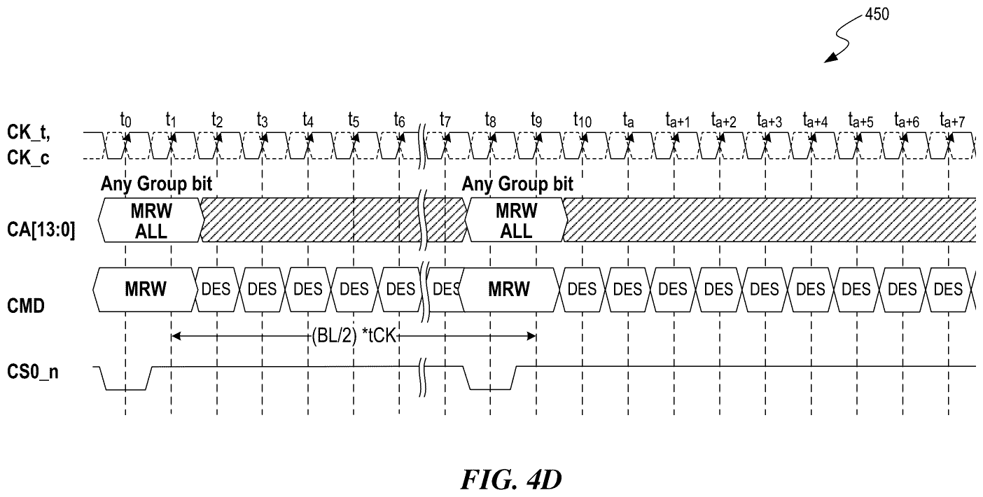

FIG. 4A is a flow diagram illustrating an example method 400 of operating devices (e.g., devices illustrated in FIGS. 1A, and/or 1B) for a MRW-ALL command in accordance with an embodiment of the present technology. The example method 400 can correspond to operations of a computing device or system, such as including the apparatus 100 (e.g., a DRAM) that is electrically coupled to the apparatus controller 102 (e.g., a memory controller). The apparatus controller 102 and the apparatus 100 can interact with each other in real-time, such as during system initialization and/or actual use by an end-user, to perform MRW-ALL operations. The apparatus controller 102 and the apparatus 100 can use the MRW-ALL operations to store data in multiple mode registers of the apparatus. As described herein, the mode registers may contain data characterizing the configuration of the apparatus 100, operational parameters of the apparatus, status of the apparatus, etc.

At block 402, the apparatus controller 102 can send an MRW-ALL command to the apparatus 100. The apparatus controller 102 can be configured to send an MRW-ALL command during operation of the corresponding system/environment. For example, the apparatus controller 102 can be configured to write data in one or more mode registers of the apparatus 100 to train an interface of the apparatus (e.g., CA/CS/CK) trainings upon system power-up or the corresponding system initialization. The MRW-ALL command sent by the apparatus controller 102 may indicate a mode register group, to which to write mode register information. For example, one or more bits used to send the MRW-ALL command (e.g., CA bits) may be used to encode a group identifier and/or individual bits may be used to designate a specific group. In an embodiment in which the apparatus 100 is coupled to a 14-bit CA interface (e.g., CA[13:0]), CA[13:11] may be used to indicate the group.

At block 404, the apparatus 100 can determine the device configuration of the apparatus, in response to receiving the MRW-ALL command from the apparatus controller 102. For example, the apparatus may activate the MRR/MRW circuit 180 of FIG. 1B. The apparatus 100 can determine one or more aspects of the device configuration that are associated with how much data the apparatus can write in response to the MRW-ALL command. For example, the apparatus 100 can determine the die configuration of the apparatus (e.g., how many DQs couple the apparatus to the apparatus controller 102) and the burst length of the apparatus.

At block 406, the apparatus 100 can identify the mode registers belonging to the group indicated by the MRW-ALL command, based on the device configuration of the apparatus. For example, during the sending of the MRW-ALL command one or more CA pins (e.g., CA11, CA12, and CA13 as illustrated in FIG. 4B) can be used to indicate the group of mode registers indicated by the apparatus controller 102. Each group defines one or more mode registers that are used to store data in response to the MRW-ALL command. As described herein, the composition of each group (e.g., the number of mode registers associated with a group, and which mode registers are associated with a group) may depend on one or more aspects of the device configuration of the apparatus 100 (e.g., the number of DQs and burst length). Furthermore, how the information is stored on the mode registers associated with the indicated group may depend on one or more aspects of the device configuration of the apparatus 100. For example, which DQ is used to write a mode register's information, and during which UIs within the burst, may be determined by the apparatus 100. The apparatus 100 may determine which mode registers belong to a given group and how the information of the mode registers is to be stored, based on the device configuration, using one or more of dedicated logic, configurable logic, look-up table, etc. For example, the apparatus 100 may include a look-up table configured to receive as inputs a group identifier and device configuration aspects, and provide as outputs the mode registers belonging to that group and how the mode register information will be stored (e.g., over which DQ during which UIs). Although described in the context of the apparatus 100, the apparatus controller 102 may include similar functionality (e.g., to determine which group to request to write information to a desired mode registers and/or to determine when to expect the mode register information to be stored over a DQ). In embodiments, not all mode registers of the apparatus 100 are associated with a group and/or some mode registers of the apparatus may be associated with more than one group. For example, in an apparatus 100 with 256 mode registers, only 64 mode registers (e.g., the mode registers that store information used during training operations) may be associated with one or more groups that can be selected by a MRR-ALL command. During a training operation, a subset of the mode registers may be written to instead of all of the mode registers.

At block 408, the apparatus controller 102 can send the information to be written to the mode registers over the DQs. As described above, the apparatus controller 102 and/or apparatus 100 can determine (e.g., at block 406) which DQ will be used to transmit the write data for each mode register in the indicated group, and at which UIs within the burst that write data will be transmitted over the DQ.

At block 410, the apparatus 100 can write the mode register contents (e.g., OP0-OP7) to one or more mode registers, in response to the MRW-ALL command. As described herein, the apparatus 100 can store data to one or more mode registers, on a DQ, over one or more UIs within a bust. For example, the apparatus 100 may write data to a first mode register over DQ0, and data to a second more register over DQ1, during first UIs of a burst (e.g., UI0-UI7), followed by writing data to a third mode register over DQ0 and data to a fourth mode register over DQ1 during second UIs of the burst (e.g., UI8-UI15). The apparatus 100 can write data to the mode registers based on the group indication of the MRW-ALL command, based on which the apparatus 100 can determine which mode registers belong to the group and how the data is stored to the mode registers (e.g., over which DQ and during which UIs), based e.g., on block 404. Since the mode registers are received over several DQs, the apparatus 100 can store mode register information from each DQ at the same time. To store the mode register information in a designated group, the apparatus controller 102 can flag the associated CA pin as “high” when issuing the MRW-ALL command.

At block 412, the apparatus 100 can send a confirmation message to the apparatus controller 102 to confirm that the MRW-ALL command was executed, and the associated mode register information was stored.

At block 414, the apparatus controller 102 can determine a configuration setting and/or status of the apparatus 100 based on the mode register information stored in response to the MRW-ALL command. For example, the apparatus controller 102 can determine a status of the apparatus 100 relevant to training.

At block 416, the apparatus controller 102, the apparatus 100, or a combination thereof can perform one or more operations based on the determined configuration settings and/or status. For example, the apparatus controller 102 and/or the apparatus 100 can adjust a setting used during training. After executing a MRW-ALL command, the apparatus controller 102, the apparatus 100, or a combination thereof can perform a high speed operation before or after completing trainings (e.g., CA/CS/CK trainings, write leveling, write trainings etc.) since MRW-ALL commands use DQ operations.

Although FIG. 4A illustrates an embodiment of the method 400 in which the apparatus 100 and/or apparatus controller 102 use mode register information write via an MRW-ALL command to perform training, information written to the mode registers may be used for other purposes of the memory system.

FIG. 4B is a diagram illustrating a command truth table 420 for a MRW-ALL command in accordance with an embodiment of the present technology. The command truth table 420 illustrates that during a first cycle of the MRW-ALL command (e.g., when CS_n is L), CA5-CA12 may be used to encode an address (MRA0-MRA7) of an individual mode register. The individual mode register address may be used to identify an individual mode register to read when, as described below, the MRW-ALL command is decoded as a MRW command. The command truth table 420 further illustrates that during a second cycle of the MRW-ALL command (e.g., when CS_n is H), CA11, CA12, and CA13 are used to indicate a group. In the embodiment illustrated in FIG. 4B, each of CA11, CA12, and CA13 indicate an individual group, e.g., CA11 indicates group A, CA12 indicates group B, and CA13 indicates group C. In embodiments in which each a CA pin indicates an individual group, zero or one of the pins may be asserted to be a valid MRW-ALL command (e.g., multiple pins cannot assert to indicate multiple groups). In embodiments (not shown), CA11-CA13 may be used to store an encoded group identifier. Although for illustrative purposes only three CA pins, associated with three groups of mode registers are shown, the current techniques can include any number of mode register groups, and indicated by encoded or decoded (e.g., zero-or one-hot) form. In embodiments, if the MRW-ALL command does not include a group identifier during the second cycle, then in response to the command the apparatus 100 can write data provided on CA0-CA7 during the second cycle of the command (OP0-OP7) into a specific mode register identified on CA5-CA13 during a first cycle of the command (MRA0-MRA7); that is, the apparatus can treat the command as a conventional MRW command. In embodiments, if the MRW-ALL command indicates a valid group identifier during the second cycle (e.g., the command will be treated as MRW-ALL), then the OP0-OP7 and MRA0-MRA7 on the corresponding CA bits can be ignored and, as described herein, the write data for the mode registers is instead transmitted over the DQs. For example, the MRA0-MRA7 bits become “don't cares” if on the next phase (when CS_n goes H) the rest of the decode indicates the MRW-ALL instruction and not an MRW instruction (e.g., based on the presence of the GA, GB, and GC bits).

FIG. 4C is a timing diagram 440 illustrating MRW-ALL command timing in accordance with an embodiment of the present technology. Timing diagram 440 illustrates that for a MRW-ALL command, a host can use different DQs to transmit the data being written to multiple mode registers during multiple UIs of a burst. For example, DQ0 is used to send data over 16 UIs (8 UIs for mode register A and 8 UIs for mode register B) of a burst, DQ1 is used to send data over 16 UIs (8 UIs for mode register C and 8 UIs for mode register D) of a burst, DQ2 is used to send data over 16 UIs (8 UIs for mode register E and 8 UIs for mode register F) of a burst, and DQ3 is used to send data over 16 UIs (8 UIs for mode register G and 8 UIs for mode register H) of a burst.

FIG. 4D is a timing diagram 450 illustrating back-to-back mode register write all commands in accordance with an embodiment of the present technology. Timing diagram 450 illustrates an example of back-to-back timing of two MRW-ALL commands. The timing gap between MRW-ALL commands is equal to half the burst length multiplied by the clock cycle (e.g., tCK). In a first example, for a burst length of 32, the timing gap between MRW-ALL commands is 16*tCK. In a second example, for a burst length of 16, the timing gap between MRW-ALL commands is 8*tCK.

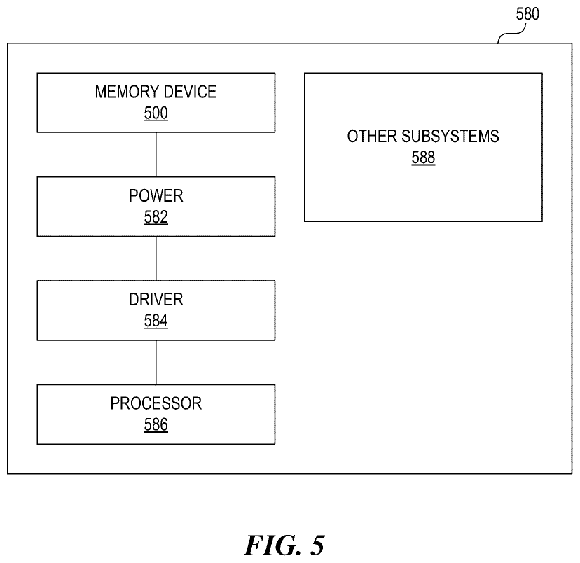

FIG. 5 is a schematic view of a system that includes an apparatus in accordance with embodiments of the present technology. Any one of the foregoing apparatuses (e.g., memory devices) described above with reference to FIGS. 1A-4D can be incorporated into any of a myriad of larger and/or more complex systems, a representative example of which is system 580 shown schematically in FIG. 5. The system 580 can include a memory device 500, a power source 582, a driver 584, a processor 586, and/or other subsystems or components 588. The memory device 500 can include features generally similar to those of the apparatus described above with reference to FIGS. 1A-4D, and can therefore include various features for performing a direct read request from a host device. The resulting system 580 can perform any of a wide variety of functions, such as memory storage, data processing, and/or other suitable functions. Accordingly, representative systems 580 can include, without limitation, hand-held devices (e.g., mobile phones, tablets, digital readers, and digital audio players), computers, vehicles, appliances and other products. Components of the system 580 may be housed in a single unit or distributed over multiple, interconnected units (e.g., through a communications network). The components of the system 580 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of DRAM devices. Apparatuses configured in accordance with other embodiments of the present technology, however, can include other types of suitable storage media in addition to or in lieu of DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structures includes information arranged as bits, words or code-words, blocks, files, input data, system generated data, such as calculated or generated data, and program data. Further, the term “dynamic” as used herein describes processes, functions, actions or implementation occurring during operation, usage or deployment of a corresponding device, system or embodiment, and after or while running manufacturer's or third-party firmware. The dynamically occurring processes, functions, actions or implementations can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1A-5.

I/we claim:

1. An apparatus, comprising:
an input/output circuit configured to communicate with an external controller, wherein the input/output circuit comprises a command/address (CA) interface and a data (DQ) interface; and
a mode register circuit coupled to the input/output circuit and configured to:
decode, on the CA interface, a command from the external controller, wherein the command comprises a mode register read all (MRR-ALL) command or a mode register write all (MRW-ALL) command;
determine a die configuration and a burst length for executing the MRR-ALL command or the MRW-ALL command; and
determine at least one group of mode registers identified in the MRR-ALL command or the MRW-ALL command,
wherein the input/output circuit is configured to send:
mode register information associated with the at least one group of mode registers identified in the MRR-ALL command to the external controller over the DQ interface.

2. The apparatus of claim 1, wherein the DQ interface comprises at least four DQs, and wherein sending the mode register information over the DQ interface comprises sending information for at least four mode registers over the at least four DQs.

3. The apparatus of claim 1, wherein the at least one group of mode registers includes a number of mode registers based on the determined die configuration and the burst length.

4. The apparatus of claim 1, wherein the determination of the at least one group of mode registers is based on an at least one group identifier received over the CA interface in association with the MRR-ALL command or the MRW-ALL command.

5. The apparatus of claim 1, wherein the DQ interface comprises a number of DQs, and wherein each DQ of the number of DQs sends different mode register information according to the burst length.

6. The apparatus of claim 1, wherein the DQ interface comprises a number of DQs, and wherein each of the DQs has a double unit interval that includes a burst length of 16.

7. The apparatus of claim 1, wherein the apparatus is a dynamic random-access memory (DRAM) that is coupled to the external controller.

8. A memory system, comprising:
a memory controller; and
a memory array operably coupled to the memory controller and configured to:
decode a command from the memory controller, wherein the command comprises a mode register read all (MRR-ALL) command or a mode register write all (MRW-ALL) command;
determine a die configuration and a burst length for executing the MRR-ALL command or the MRW-ALL command;
determine at least one group of mode registers identified in the MRR-ALL command or the MRW-ALL command; and
send mode register information associated with the at least one group of mode registers identified in the MRR-ALL command to the memory controller.

9. The memory system of claim 8, wherein the memory array comprises at least four DQs, and wherein sending the mode register information comprises sending information for at least four mode registers over the at least four DQs.

10. The memory system of claim 8, wherein the at least one group of mode registers includes a number of mode registers based on the determined die configuration and the burst length.

11. The memory system of claim 8, wherein the determination of the at least one group of mode registers is based on an at least one group identifier received in association with the MRR-ALL command or the MRW-ALL command.

12. The memory system of claim 8, wherein the memory array comprises a number of DQs, and wherein each DQ of the number of DQs sends different mode register information according to the burst length.

13. The memory system of claim 8, wherein the memory array comprises a number of DQs, and wherein each of the DQs has a double unit interval that includes a burst length of 16.

14. The memory system of claim 8, wherein the memory array is a dynamic random-access memory (DRAM).

15. A method of operating an apparatus, the method comprising:
decoding a command from an external controller, wherein the command comprises a mode register read all (MRR-ALL) command or a mode register write all (MRW-ALL) command;
determining a die configuration and a burst length for executing the MRR-ALL command or the MRW-ALL command;
determining at least one group of mode registers identified in the MRR-ALL command or the MRW-ALL command; and
sending mode register information associated with the at least one group of mode registers identified in the MRR-ALL command to the external controller.

16. The method of claim 15, wherein the apparatus comprises at least four DQs, and wherein sending the mode register information comprises sending information for at least four mode registers over the at least four DQs.

17. The method of claim 15, wherein the at least one group of mode registers includes a number of mode registers based on the determined die configuration and the burst length.

18. The method of claim 15, wherein the determination of the at least one group of mode registers is based on an at least one group identifier received interface in association with the MRR-ALL command or the MRW-ALL command.

19. The method of claim 15, wherein the apparatus comprises a number of DQs, and wherein each DQ of the number of DQs sends different mode register information according to the burst length.

20. The method of claim 15, wherein the apparatus comprises a number of DQs, and wherein each of the DQs has a double unit interval that includes a burst length of 16.
